(19) United States
(12) Patent Application Publication
(10) Pub. No.: US 2012/0223349 A1
(43) Pub. Date: Sep. 6, 2012

(54) FRONT SIDE EMITTING TYPE ORGANIC LIGHT-EMITTING DISPLAY DEVICE AND METHOD OF MANUFACTURING THE SAME

(75) Inventors: Chang-Ho Lee, Yongin-city (KR); Hee-Joo Ko, Yongin-city (KR); Hyung-Jun Song, Yongin-city (KR); Il-Soo Oh, Yongin-city (KR); Jin-Young Yun, Yongin-city (KR); Bo-Ra Lee, Yongin-city (KR); Se-Jin Cho, Yongin-city (KR); Young-Woo Song, Yongin-city (KR); Jong-Hyuk Lee, Yongin-city (KR); Sung-Chul Kim, Yongin-city (KR)

(73) Assignee: Samsung Mobile Display Co., Ltd., Yongin-city (KR)

(21) Appl. No.: 13/282,347

(22) Filed: Oct. 26, 2011

(30) Foreign Application Priority Data
Mar. 4, 2011 (KR) 10-2011-0019331

(51) Int. Cl. H01L 27/32; H01L 51/56; H01L 51/52

(52) U.S. Cl. 257/98; 257/99; 438/23; 257/40; 257/E27.119; 257/E51.019; 257/E51.018

(57) ABSTRACT

A front side emitting type organic light-emitting display device includes a substrate; an anode electrode formed over the substrate; an organic layer formed over the anode electrode; a cathode electrode formed over the organic layer; a pair of transparent conductive oxide layers disposed over the cathode electrode; and a metal layer interposed between the pair of transparent conductive oxide layers.

This application claims priority from Korean Patent Application No. 10-2011-0019331 filed on Mar. 4, 2011 in the Korean Intellectual Property Office, the disclosure of which is incorporated herein by reference in its entirety.

### BACKGROUND

1. Field

The present disclosure relates to a front side emitting type organic light-emitting display device and a method of manufacturing the same, and more particularly, to a front side emitting type organic light-emitting display device including a cathode electrode with low resistance.

2. Description of the Related Art

The rapid development of the information and technology (IT) industry is dramatically increasing the use of display devices. Recently, there have been demands for display devices that are lightweight and thin, consume low power and provide high resolution. To meet these demands, liquid crystal displays or organic light-emitting displays using organic light-emitting characteristics are being developed.

In an organic light-emitting element, holes and electrons injected from an external source combine together in a light emitting layer to form excitons as they disappear. The excitons transfer energy to fluorescent molecules of the light emitting layer as they transit from an excited state to a ground state. Then, the fluorescent molecules emit light to form an image. In terms of energy state, excitons have one singlet state and three triplet states. Excitons, by the nature of band gap energy, emit light in a singlet energy state but do not emit light in a triplet energy state and are converted into thermal energy.

An organic light-emitting element includes an anode layer formed in a predetermined pattern on a substrate, a hole transporting layer, an light emitting layer and an electron transporting layer sequentially stacked on the anode layer, and a cathode layer formed in a predetermined pattern on a top surface of the electron transporting layer in a direction orthogonal to the anode layer. Here, the hole transporting layer, the light emitting layer and the electron transporting layer are organic thin films made of an organic compound.

Organic light-emitting displays, which are next-generation display devices having self light-emitting characteristic, have better characteristics than liquid crystal displays in terms of viewing angle, contrast, response speed and power consumption, and can be manufactured to be thin and lightweight since a backlight is not required.

Hereinafter, the structure of an organic light-emitting display device and a method of manufacturing the organic light-emitting display device will be described with reference to FIGS. 1 through 3. In FIGS. 1 through 3, a front side emitting type organic light-emitting display device in which light is emitted upward in FIG. 1 or 2 will be described as an example. FIGS. 1 and 2 are cross-sectional views of an organic light-emitting display device. FIG. 3 is a flowchart illustrating a method of manufacturing the organic light-emitting display device.

Referring to FIG. 1, the organic light-emitting display device includes an anode electrode 3 formed on a lower substrate 1, an organic layer 4 formed on the anode electrode 3, and a cathode electrode 5 and an upper substrate 6 sequentially stacked on the organic layer 4.

The organic layer 4 includes a hole injecting layer 4a, a hole transporting layer 4b, a light emitting layer 4c, an electron transporting layer 4d, and an electron injecting layer 4e stacked sequentially.

As described above, holes injected from the hole injecting layer 4a and electrons injected from the electron injecting layer 4e combine in the light emitting layer 4c to generate light, and the generated light is emitted upward in FIG. 1 to pass through the cathode electrode 5 and the upper substrate 6 and then exit the display device.

In such a front side emitting-type organic light-emitting display device, a thickness of the cathode electrode 5 needs to be reduced in order to improve light transmittance as shown in FIG. 2. However, a reduction in the thickness of the cathode electrode 5 increases a resistance value of the cathode electrode 5, resulting in non-uniform luminance.

In addition, to implement the upper substrate 6 for encapsulation on the cathode electrode 5 of the organic light-emitting display device, an additional encapsulation process should be performed as shown in FIG. 3. The additional encapsulation process increases the manufacturing time.

The foregoing discussion of the background section is to provide general background information, and does not constitute an admission of the prior art.

### SUMMARY

Aspects of the present invention provide a front side emitting type organic light-emitting display device which includes a cathode electrode with high light transmittance and a low resistance value.

Aspects of the present invention also provide a front side emitting type organic light-emitting display device which can be manufactured without requiring an additional encapsulation process after the formation of a cathode electrode.

However, aspects of the present invention are not restricted to the one set forth herein. The above and other aspects of the present invention will become more apparent to one of ordinary skill in the art to which the present invention pertains by referencing the detailed description given below.

According to an aspect of the present invention, there is provided a front side emitting type organic light-emitting display device comprising: a substrate; an anode electrode formed over the substrate; an organic layer formed over the anode electrode; a cathode electrode formed over the organic layer; a pair of transparent conductive oxide layers disposed over the cathode electrode; and a metal layer interposed between the pair of transparent conductive oxide layers.

According to another aspect of the present invention, there is provided A front side emitting type organic light-emitting display device comprising: a substrate having a pixel region, a transistor region and a capacitor region; a thin-film transistor formed in the transistor region; a cathode electrode formed over the thin-film transistor; a plurality of transparent conductive oxide layers electrically connected to the cathode electrode; and a plurality of metal layers electrically connected to the plurality of transparent conductive oxide layers; wherein the plurality of transparent conductive oxide layers and the plurality of metal layers are alternately stacked to form a stack of the plurality of transparent conductive oxide layers and the plurality of metal layers disposed over the cathode electrode, wherein one of the plurality of transparent conductive oxide layers is disposed at the top of the stack.

According to another aspect of the present invention, there is provided a method of manufacturing a front side emitting type organic light-emitting display device, the method comprising: providing a lower substrate; defining a thin-film transistor region, a capacitor region and a pixel region of the lower substrate; forming an organic layer over an anode electrode disposed over the pixel region; forming a cathode electrode over the organic layer; sequentially providing a transparent conductive oxide layer and a metal layer over the cathode electrode; and providing an additional transparent conductive oxide layer over the metal layer.

According to another aspect of the present invention, there is provided a method of manufacturing a front side emitting type organic light-emitting display device, the method comprising: providing a lower substrate; defining a thin-film transistor region, a capacitor region and a pixel region of the lower substrate; forming an organic layer over an anode electrode disposed over the pixel region; forming a cathode electrode over the organic layer; alternately stacking a plurality of transparent conductive oxide layers and a plurality of metal layers over the cathode electrode to form a stack; and providing an additional transparent conductive oxide layer over the stack of the plurality of transparent conductive oxide layers and the plurality of metal layers.

### BRIEF DESCRIPTION OF THE DRAWINGS

The above and other aspects and features of the present invention will become more apparent by describing in detail embodiments thereof with reference to the attached drawings, in which:

FIGS. 1 and 2 are cross-sectional views of an organic light-emitting display device;

FIG. 3 is a flowchart illustrating a method of manufacturing the organic light-emitting display device;

FIG. 4 is a cross-sectional view of a front side emitting type organic light-emitting display device according to an embodiment of the present invention;

FIGS. 5 and 6 are cross-sectional views of a front side emitting type organic light-emitting display device according to another embodiment of the present invention;

FIG. 7 is a flowchart illustrating a method of manufacturing a front side emitting type organic light-emitting display device according to an embodiment of the present invention; and

FIG. 8 is a flowchart illustrating a method of manufacturing a front side emitting type organic light-emitting display device according to another embodiment of the present invention.

### DETAILED DESCRIPTION OF EMBODIMENTS

Embodiments of the present will now be described more fully hereinafter with reference to the accompanying drawings, in which embodiments of the invention are shown. This invention may, however, be embodied in different forms and should not be construed as limited to the embodiments set forth herein. Rather, these embodiments are provided so that this disclosure will be thorough and complete, and will fully convey the scope of the invention to those skilled in the art. The same reference numbers indicate the same components throughout the specification. In the attached figures, the thickness of layers and regions is exaggerated for clarity.

It will also be understood that when a layer is referred to as being “on” another layer or substrate, it can be directly on the other layer or substrate, or intervening layers may also be present. In contrast, when an element is referred to as being “directly on” another element, there are no intervening elements present.

Spatially relative terms, such as “beneath,” “below,” “lower,” “above,” “upper” and the like, may be used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” other elements or features would then be oriented “above” the other elements or features. Thus, the term “below” can encompass both an orientation of above and below. The device may be otherwise oriented (rotated 90 degrees or at other orientations) and the spatially relative descriptors used herein interpreted accordingly.

The use of the terms “a” and “an” and “the” and similar referents in the context of describing the invention (especially in the context of the following claims) are to be construed to cover both the singular and the plural, unless otherwise indicated herein or clearly contradicted by context. The terms “comprising,” “having,” “including,” and “containing” are to be construed as open-ended terms (i.e., meaning “including, but not limited to,”) unless otherwise noted.

Unless defined otherwise, all technical and scientific terms used herein have the same meaning as commonly understood by one of ordinary skill in the art to which this invention belongs. It is noted that the use of any and all examples, or terms provided herein is intended merely to better illuminate the invention and is not a limitation on the scope of the invention unless otherwise specified. Further, unless defined otherwise, all terms defined in generally used dictionaries may not be overly interpreted.

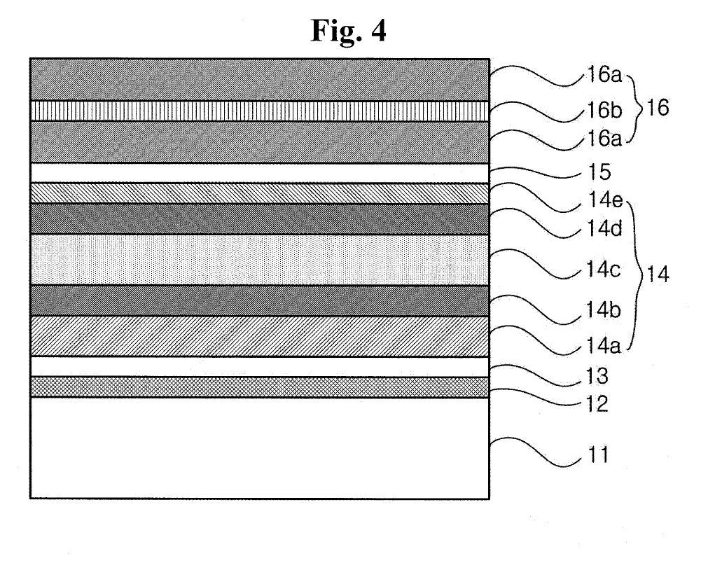

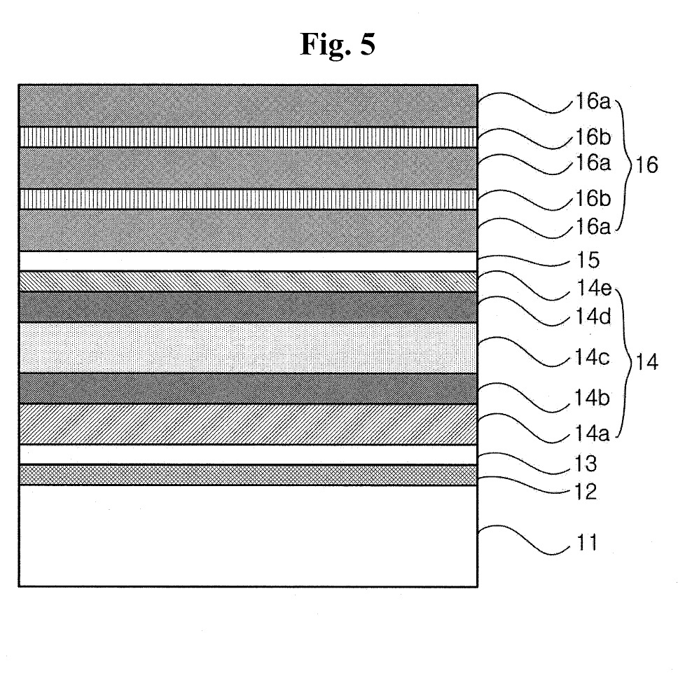

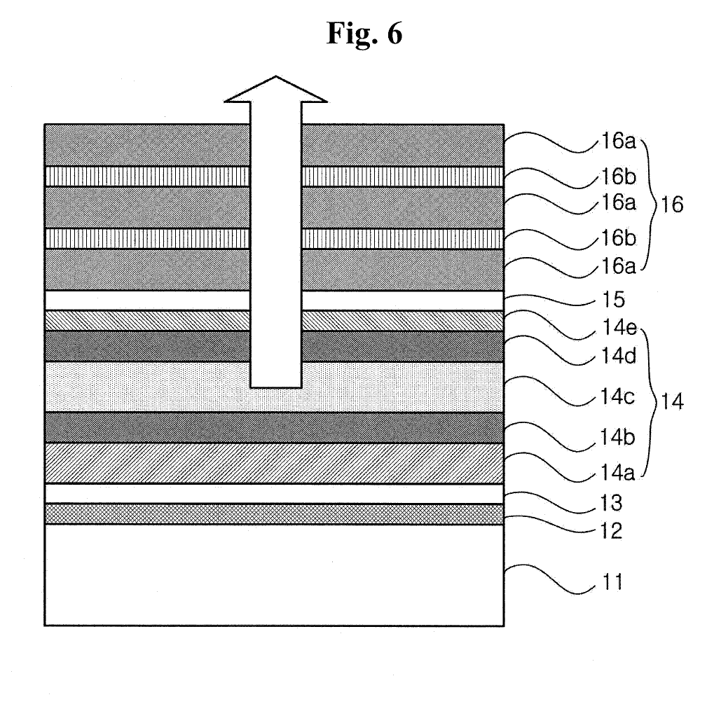

Hereinafter, front side emitting type organic light-emitting display devices according to embodiments will be described with reference to FIGS. 4 through 6. FIG. 4 is a cross-sectional view of a front side emitting type organic light-emitting display device according to an embodiment of the present invention. FIGS. 5 and 6 are cross-sectional views of a front side emitting type organic light-emitting display device according to an embodiment of the present invention.

Referring to FIG. 4, the front side emitting type organic light-emitting display device according to the embodiment includes a substrate 11, an anode electrode formed on the substrate 11, an organic layer 14 formed on the anode electrode 13, a cathode electrode 15 formed on the organic layer 14, a pair of transparent conductive oxides 16a formed on the cathode electrode 15, and a metal layer 16b interposed between the transparent conductive oxides 16a.

Specifically, the substrate 11 may be made of a transparent glass material containing SiO₂ as a main component. However, the material that forms the substrate 11 is not limited to the transparent glass material. The substrate 11 may also be made of a transparent plastic material. The plastic material that forms the substrate 11 may be an insulating organic material selected from the group consisting of polyethersulphone (PES), polyacrylate (PAR), polyetherimide (PEI), polyethylene napthalate (PEN), polyethylene terephthalate (PET), polyphenylene sulfide (PPS), polyallylate, polyimide, polycarbonate (PC), cellulose triacetate (TAC), and cellulose acetate propionate (CAP).

A transistor region, a capacitor region and a pixel region in which a transistor, a capacitor and a pixel are formed respectively may be defined on the substrate 11. There are no clear boundaries between the transistor region, the capacitor region and the pixel region. Thus, a region in which a transistor is formed on the substrate 11 is defined as the transistor region, and a region in which a capacitor is formed on the substrate 11 is defined as the capacitor region.

In a bottom emission organic light-emitting display device in which an image is realized toward the substrate 11, the substrate 11 should be made of a transparent material. However, in a top emission organic light-emitting display device in which an image is realized away from the substrate 11, the substrate 11 may not necessarily be made of a transparent material. In this case, the substrate 11 may be made of metal. When the substrate 11 is made of metal, it may contain one or more materials selected from the group consisting of Fe, Cr, Mn, Ni, Ti, Mo, and stainless steel. However, the material that forms the substrate 11 is not limited to the above materials. The substrate 11 may also be made of a metal foil.

A buffer layer (not shown) may further be formed on the substrate 11 to planarize the substrate 11 and prevent penetration of impurities into the substrate 11. The buffer layer may be a single layer of SiOx, SiNx or SiO2Nx, or a multilayer structure of these materials.

As shown in FIG. 4, a reflective film 12 may further be formed between the substrate 11 and the anode electrode 13. The reflective film 12 included in the front side emitting type organic light-emitting display device according to an embodiment reflects light which is emitted from an light emitting layer 14c toward the back side of the display device, such that the light proceeds toward the front side, thereby improving light efficiency.

The optical resonance effect between the reflective film 12 and the cathode electrode 15 enables more light to proceed toward the cathode electrode 15.

The reflective film 12 may be made of any material, preferably, a material with high light reflectance, such as metal. The thickness of the reflective film 12 may also be adjusted to ensure sufficient light reflection. The reflective film 12 may be made of Al, Ag, Cr or Mo and may be formed to a thickness of approximately 1,000 Å.

The anode electrode 13 is formed on the reflective film 12. In a bottom emission organic light-emitting display device, the anode electrode 13 may be a transparent conductive material such as indium tin oxide (ITO) or indium zinc oxide (IZO). In the front side emitting type organic light-emitting display device according to an embodiment, the anode electrode 13 may be formed by depositing a metal oxide with a high work function, such as Al₂O₃ or ZnO, on the reflective film 12.

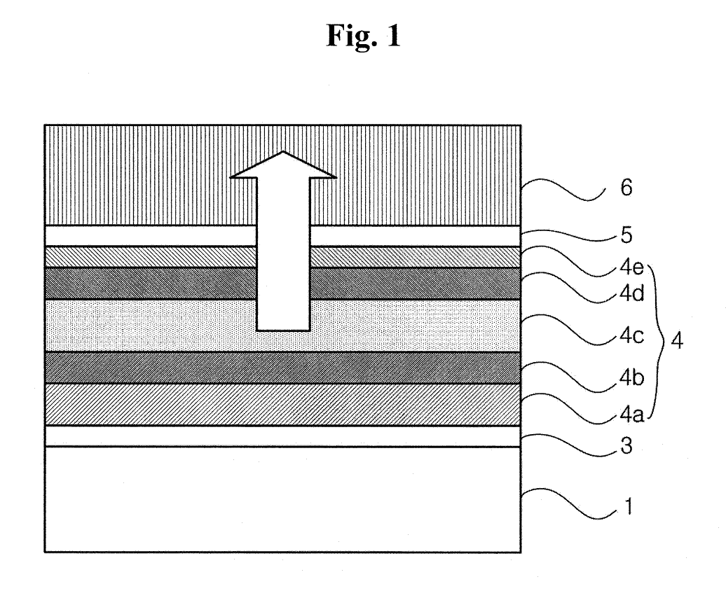

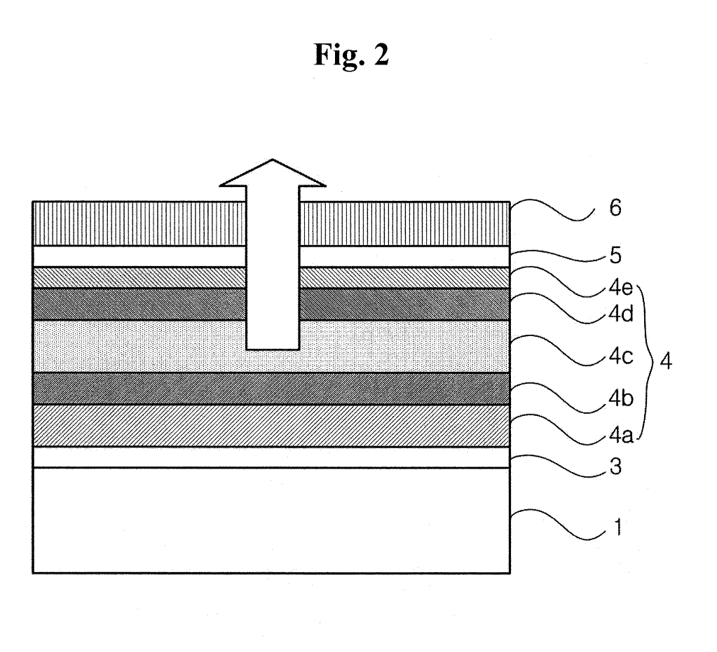

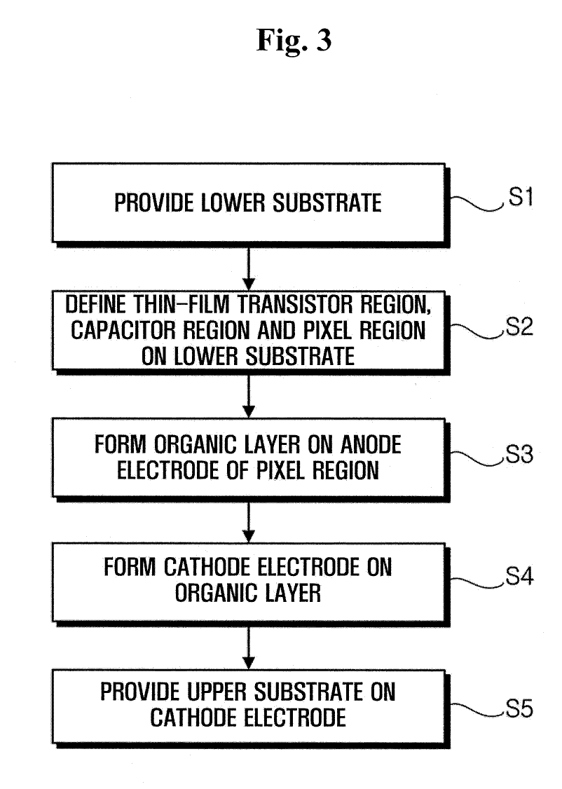

The organic layer 14 is formed on the anode electrode 13. As described above, the organic layer 14 includes a hole injecting layer 14a, a hole transporting layer 14b, the light emitting layer 14c, an electron transporting layer 14d, and an electron injecting layer 14e stacked sequentially. Holes injected from the hole injecting layer 14a and electrons injected from the electron injecting layer 14e combine together in the light emitting layer 14c to generate light, and the generated light is emitted upward in FIG. 1 to pass through the cathode electrode 15 and then exit the display device.

The organic layer 14 may further include an auxiliary hole transporting layer which helps holes to easily reach the light emitting layer 14c.

The cathode electrode 15 generates an electric field together with the anode electrode 13 thereunder, thereby causing the light emitting layer 14c to emit light. In the front side emitting type organic light-emitting display device according to an embodiment, the cathode electrode 15 may be made of a material that allows light to pass therethrough, specifically, a metal with a low work function. The cathode electrode 15 may be formed thin to be able to be a semi-transmissive reflection. A metal with a low work function, such as Mg, Ag, Al, Au or Cr, may be used for the cathode electrode 15.

The pair of transparent conductive oxide layers 16a are stacked over the cathode electrode 15, and the metal layer 16b is interposed between the transparent conductive oxide layers 16a. The transparent conductive oxide layers 16a and the metal layer 16b constitute a capping layer 16. That is, the capping layer 16 may have a multilayer configuration of TCO-metal-TCO stacked sequentially. The transparent conductive oxide layers 16a may contain one or more materials selected from an InO-based material and a ZnO-based material.

The metal layer 16b interposed between the transparent conductive oxide layers 16a reduces the resistance between the transparent conductive oxide layers 16a. Since light emitted from the light emitting layer 14c transmits through the metal layer 16b to travel toward the front side of the display device, the metal layer 16 may be made of a metal with a light transmittance of about 80% or more. Specifically, the metal layer 16b may be made of Ag with high light transmittance and high conductivity.

The capping layer 16 including the pair of transparent conductive oxide layers 16a and the metal layer 16b interposed therebetween has high light transmittance and low resistance. Therefore, the capping layer 16 formed on the cathode electrode 15 which is manufactured thin and has high resistance can reduce the resistance of the cathode electrode 15. That is, since the capping layer 16 and the thin cathode electrode 15 are electrically coupled to form a single cathode structure, resistance can be significantly reduced. This results in uniform luminance across the entire surface of the display device.

In addition, the cathode electrode 15, the transparent conductive oxide layers 16a and the metal layer 16b have high light transmittance. Therefore, the front side emitting type organic light-emitting display device can be easily realized.

The pair of transparent conductive oxide layers 16a and the metal layer 16b interposed between them have low moisture permeability. The low moisture permeability allows them to function as a capping structure which protects internal components from external stimuli or foreign substances without using a thin encapsulation film or capping glass.

Accordingly, no additional process for providing a thin encapsulation film or capping glass is required. This provides a reduction in manufacturing time and cost.

Referring to FIGS. 5 and 6, the front side emitting type organic light-emitting display device according to an embodiment includes a substrate 11, an anode electrode 13 formed on the substrate 11, an organic layer 14 formed on the anode electrode 13, a cathode electrode 15 formed on the organic layer 14, a plurality of transparent conductive oxide layers 16a electrically connected to the cathode electrode 15, and a plurality of metal layers 16b electrically connected to the transparent conductive oxide 16a. The transparent conductive oxide layers 16a and the metal layers 16b are alternately and/or repeatedly stacked on the cathode electrode 15 to form a stack of the transparent conductive oxide layers and the metal layers. One of the transparent conductive oxide layers 16a is disposed at the top of the stack.

As shown in FIG. 5, the front side emitting type organic light-emitting display device according to the illustrated embodiment has the same structure as the front side emitting type organic light-emitting display device according to the previous embodiment, except that the transparent conductive oxide layers 16a more than two and the metal layers 16b more than two are provided to form a capping layer 16 and that the transparent oxide layers 16a and the metal layers 16b are alternately and/or repeatedly stacked on the cathode electrode 15. One of the transparent conductive oxide layers 16a is disposed at the top of the capping layer 16.

That is, the capping structure of the present embodiment has more layers stacked on the cathode electrode 15 than that of the previous embodiment. Thus, the resistance of the entire cathode structure of the present embodiment including the cathode electrode 15 and the layers 16a and 16b can be further reduced.

The transparent conductive oxide layers 16a and the metal layers 16b stacked repeatedly have excellent light transmittance. Therefore, light emitted from a light emitting layer 14c can pass through the cathode electrode 15 and the capping layer 16 to form an image on the display device, as shown in FIG. 6.

As described above in the previous embodiment, the transparent conductive oxide layers 16a may contain one or more materials selected from an InO-based material and a ZnO-based material. The metal layers 16b may be made of a metal with a light transmittance of about 80% or more. Specifically, the metal layers 16b may be made of Ag.

Although not explicitly shown in the drawings, the cathode electrode 15 and the capping layer 16 according to the above-described embodiments may be formed on a thin-film transistor formed over another region of the substrate 11.

That is, a front side emitting type organic light-emitting display device according to embodiments of the present invention includes a substrate 11 having a pixel region, a transistor region and a capacitor region, a thin-film transistor formed on the transistor region, a cathode electrode 15 formed on the thin-film transistor, a plurality of transparent conductive oxide layers 16a formed electrically connected to the cathode electrode 15, and a plurality of metal layers 16b electrically connected to the transparent conductive oxide 16a. The transparent conductive oxide layers 16a and the metal layers 16 are alternately and/or repeatedly stacked over the cathode electrode 15 to form a stack. One of the transparent conductive oxide layers 16a is disposed at the top of the stack.

Here, the thin-film transistor is connected to the anode electrode 13. Thus, a current may be selectively supplied to the anode electrode 13 under the control of the thin-film transistor. As such, the thin-film transistor controls generation of an electric field between the anode electrode 13 and the cathode electrode 15 and ultimately controls light emission of an light emitting layer 14c.

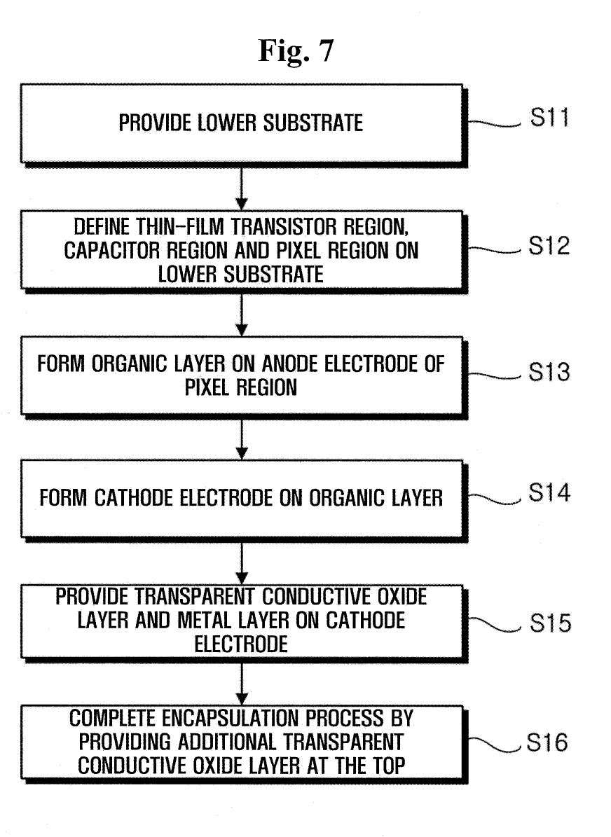

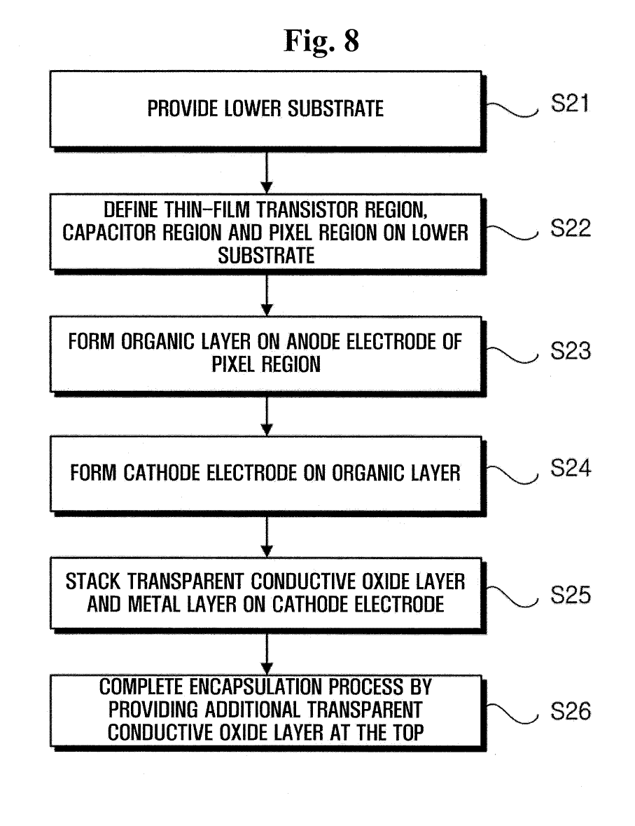

Hereinafter, methods of manufacturing a front side emitting type organic light-emitting display device according to embodiments of the present invention will be described with reference to FIGS. 7 and 8. FIG. 7 is a flowchart illustrating a method of manufacturing a front side emitting type organic light-emitting display device according to an embodiment illustrated in FIG. 4. FIG. 8 is a flowchart illustrating a method of manufacturing a front side emitting type organic light-emitting display device according to an embodiment illustrated in FIGS. 5 and 6.

Referring to FIG. 7, the method of manufacturing a front side emitting type organic light-emitting display device includes providing a lower substrate (operation S11), defining a thin-film transistor region, a capacitor region and a pixel region on the lower substrate (operation S12), forming an organic layer on an anode electrode formed over the pixel region (operation S13), forming a cathode electrode on the organic layer (operation S14), sequentially providing a transparent conductive oxide layer and a metal layer on the cathode electrode (operation S15), and providing an additional transparent conductive oxide layer on the metal layer (operation S16).

Specifically, a lower substrate is provided (operation S11). As described above, the lower substrate may be made of a transparent glass material or a plastic material. In a top emission organic light-emitting display device, the lower substrate may not necessarily be made of a transparent material. When the lower substrate is made of metal, it may contain one or more materials selected from the group consisting of Fe, Cr, Mn, Ni, Ti, Mo, and stainless steel.

A thin-film transistor region, a capacitor region and a pixel region are defined on the lower substrate, and a thin-film transistor, a capacitor and a pixel are formed in the thin-film transistor region, the capacitor region and the pixel region, respectively (operation S12). The thin-film transistor controls an anode electrode according to a gate voltage received from an external source, and the capacitor generates a sustain voltage to make the thin-film transistor be driven at a constant voltage. On the pixel region, a pixel which actually emits light using an organic layer therein and is connected to the anode electrode is formed.

Next, the organic layer is formed on the anode electrode formed over the pixel region (operation S13). As described above, the organic layer includes layers providing and transporting electrons and holes and a light emitting layer in which the electrons and the holes combine to generate light.

A cathode electrode is formed on the organic layer (operation S14), a transparent conductive oxide layer and a metal layer are sequentially provided on the cathode electrode (operation S15), and an additional transparent conductive oxide layer is provided on the metal layer (operation S16), thereby completing the entire capping process.

Referring to FIG. 8, the method of manufacturing a front side emitting type organic light-emitting display device according to an embodiment includes providing a lower substrate (operation S21), defining a thin-film transistor region, a capacitor region and a pixel region of the lower substrate (operation S22), forming an organic layer on an anode electrode formed over the pixel region (operation S23), forming a cathode electrode on the organic layer (operation S24), alternately and/or repeatedly stacking transparent conductive oxide layers and metal layers on the cathode electrode (operation S25), and providing an additional transparent conductive oxide layer at the top of the stack of the transparent conductive oxide layers and the metal layers (operation S26).

The manufacturing method according to the embodiment illustrated in FIG. 7 is the same as the manufacturing method according to the embodiment illustrated in FIG. 8, except that the transparent conductive oxide layers more than two and the metal layers more than two are alternately and/or repeatedly provided on the cathode electrode.

Since the transparent conductive oxide layers and the metal layers form a capping layer, a capping process can be performed without an additional thin-film encapsulation process. This simplifies the manufacturing process, bringing advantages in terms of time and cost.

In concluding the detailed description, those skilled in the art will appreciate that many variations and modifications can be made to the embodiments without substantially departing from the principles of the present invention. Therefore, the disclosed embodiments of the invention are used in a generic and descriptive sense only and not for purposes of limitation.

What is claimed is:

1. A front side emitting type organic light-emitting display device comprising:
a substrate;
an anode electrode formed over the substrate;
an organic layer formed over the anode electrode;
a cathode electrode formed over the organic layer;
a pair of transparent conductive oxide layers disposed over the cathode electrode; and
a metal layer interposed between the pair of transparent conductive oxide layers.

2. A front side emitting type organic light-emitting display device comprising:
a substrate;
an anode electrode formed over the substrate;
an organic layer formed over the anode electrode;
a cathode electrode formed over the organic layer;
a plurality of transparent conductive oxide layers electrically connected to the cathode electrode; and
a plurality of metal layers electrically connected to the plurality of transparent conductive oxide layers,
wherein the plurality of transparent conductive oxide layers and the plurality of metal layers are alternately stacked to form a stack of the plurality of transparent conductive oxide layers and the plurality of metal layers disposed over the cathode electrode, wherein one of the plurality of transparent conductive oxide layers is disposed at the top of the stack.

3. The display device of claim 1, wherein the organic layer comprises a hole injecting layer, a hole transporting layer, an light emitting layer, an electron transporting layer, and an electron injecting layer.

4. The display device of claim 3, wherein the organic layer further comprises an auxiliary hole transporting layer.

5. The display device of claim 1, wherein each transparent conductive oxide layer contains one or more materials selected from an indium oxide-based material and a zinc oxide-based material.

6. The display device of claim 1, wherein the metal layer is made of a metal with a light transmittance of 80% or more.

7. The display device of claim 1, wherein the metal layer is made of silver.

8. The display device of claim 1, further comprising a reflective film between the substrate and the anode electrode.

9. A front side emitting type organic light-emitting display device comprising:
a substrate having a pixel region, a transistor region and a capacitor region;
a thin-film transistor formed in the transistor region;
a cathode electrode formed over the thin-film transistor;
a plurality of transparent conductive oxide layers electrically connected to the cathode electrode; and
a plurality of metal layers electrically connected to the plurality of transparent conductive oxide layers;
wherein the plurality of transparent conductive oxide layers and the plurality of metal layers are alternately stacked to form a stack of the plurality of transparent conductive oxide layers and the plurality of metal layers disposed over the cathode electrode, wherein one of the plurality of transparent conductive oxide layers is disposed at the top of the stack.

10. The display device of claim 9, wherein each of the plurality of transparent conductive oxide layers contains one or more materials selected from an indium oxide-based material and a zinc oxide-based material.

11. The display device of claim 9, wherein the metal layer is made of a metal with a light transmittance of 80% or more.

12. The display device of claim 9, wherein the metal layer is made of silver.

13. A method of manufacturing a front side emitting type organic light-emitting display device, the method comprising:
providing a lower substrate;
defining a thin-film transistor region, a capacitor region and a pixel region of the lower substrate;
forming an organic layer over an anode electrode disposed over the pixel region;
forming a cathode electrode over the organic layer;
sequentially providing a transparent conductive oxide layer and a metal layer over the cathode electrode; and
forming an additional transparent conductive oxide layer over the metal layer.

14. A method of manufacturing a front side emitting type organic light-emitting display device, the method comprising:
providing a lower substrate;
defining a thin-film transistor region, a capacitor region and a pixel region of the lower substrate;
forming an organic layer over an anode electrode disposed over the pixel region;
forming a cathode electrode over the organic layer;
alternately stacking a plurality of transparent conductive oxide layers and a plurality of metal layers over the cathode electrode to form a stack; and
forming an additional transparent conductive oxide layer over the stack of the plurality of transparent conductive oxide layers and the plurality of metal layers.

15. The method of claim 13, wherein the forming of the organic layer comprises sequentially forming a hole injecting layer, a hole transporting layer, an light emitting layer, an electron transporting layer, and an electron injecting layer.

16. The method of claim 15, wherein the forming of the organic layer further comprises forming an auxiliary hole transporting layer.

17. The method of claim 13, wherein the transparent conductive oxide contains one or more materials selected from an indium oxide-based material and a zinc oxide-based material.

18. The method of claim 13, wherein the metal layer is made of a metal with a light transmittance of 80% or more.

19. The method of claim 13, wherein the metal layer is made of silver.
